(19) United States
(12) Patent Application Publication
(10) Pub. No.: US 2012/0044015 A1
(43) Pub. Date: Feb. 23, 2012

(54) Universal Digital Input Module in a Process Automation Controller

(75) Inventor: Ashish Magu, Arundel (GB)

(73) Assignee: Invensys Systems Inc., Foxboro, MA (US)

(21) Appl. No.: 12/858,186

(22) Filed: Aug. 17, 2010

(51) Int. Cl. H03K 3/01; H03H 11/40

(52) U.S. Cl. 327/534; 327/524

(57) ABSTRACT

In a process automation controller, a universal digital input module is provided. The universal digital input module comprises a plurality of digital input channels, each channel to sink a first current at a first voltage level associated with an input having a digital high value and to sink a second current at a second voltage level associated with the input having a digital high value, wherein the first current is greater than the second current and wherein the first voltage is less than the second voltage.

### CROSS-REFERENCE TO RELATED APPLICATIONS

None.

### STATEMENT REGARDING FEDERALLY SPONSORED RESEARCH OR DEVELOPMENT

Not applicable.

### REFERENCE TO A MICROFICHE APPENDIX

Not applicable.

### BACKGROUND

Process automation and automated control have experienced great growth over the last sixty-five years and have contributed to strong productivity growth in industry, as manual operations performed by human beings have been replaced by automatically controlled operations. One may categorize automated control into discrete automation, batch control, and process control.

Discrete automation may be exemplified by an automated canning or bottling line: content is deposited in the container, the container is sealed, and the container is packaged for shipment, while the materials are moved along one or more conveyors possibly handled by a number of automated stations performing an operation. Discrete automation may also be exemplified by an automobile assembly line. Discrete automation controllers may monitor events such as the passage of a container past an electric eye, the opening and/or closing of a gate, and other events. Discrete automation controllers may turn conveyors on and off, may open and/or close gates, may open and close valves in response to control strategies or control logic and in response to the monitored events.

Batch control may be exemplified by chemical processing where several materials are flowing together and are heated to a desired temperature and pressure and perhaps agitated or processed in a centrifuge. Batch control may be involved in brewing beer and fabricating pharmaceuticals. Batch control controllers may monitor temperatures, pressures, fluid flow velocities, weights, and other parameters. Batch control may send control commands to modulate valves and motors to achieve desired control parameters. When the batch of material has been processed, the batch is completed. Alternatively, at the completion of batch processing, water, barley malt, hops, and syrup have been fermented and transformed into beer ready for bottling.

Process control may also be referred to as continuous process control. Process control may be exemplified by a glass fabrication plant or by a crude oil fractionating plant (also referred to in some contexts as an oil refinery). It is the nature of these processes that they are most economically operated when they run continuously. For example, shutting down a glass manufacturing plant to make a repair or to replace equipment may entail substantial start-up costs involved in bringing one or more ovens back up to operating temperatures. Likewise, unexpected interruption of a continuous process, for example caused by a component failure, may cause losses related to damaged product. A process controller may monitor temperatures, pressures, fluid flow, weights, valve positions, motor speeds, electrical currents, and other parameters.

The process controller may monitor a discrete input from an electrical contactor mechanically coupled to a monitored device—for example a limit switch coupled to an open position of a valve or a closed position of a valve. In some embodiments, the process controller may source a voltage to a first contact point of the contactor. When the contactor is open, there is no path for electrical flow through the contactor, and a monitoring line from the process controller that is coupled to a second contact point of the contactor senses no voltage and/or current flow through the contractor. When the contactor is closed, a conduction path between the first and second contact points is established, and the monitoring line from the process controller senses voltage and current conduction. A process controller may supply about 18 volts electrical power to a contactor. After accounting for voltage drops in the electronic circuitry, the voltage sensed by the process controller when a contactor is closed may be about 12 volts. This diminished voltage sensed by the process controller may be referred to in some contexts as a wetting voltage. The process controller may modulate these physical parameters using analog outputs as well as discrete outputs. The analog output may comprise a voltage that varies substantially continuously from about a zero volts voltage level to about a ten volts voltage level with currents in the range from 0 milliamps to about 20 milliamps. The voltage and current levels indicated above may be different in some cases and with different equipment.

### SUMMARY

In an embodiment, a universal digital input module for use in a process automation controller is disclosed. The universal digital input module comprises a plurality of digital input channels, each channel to sink a first current at a first voltage level associated with an input having a digital high value and to sink a second current at a second voltage level associated with the input having a digital high value, wherein the first current is greater than the second current and wherein the first voltage is less than the second voltage.

In an embodiment, a method of receiving a discrete input in a process automation controller is disclosed. The method comprises in response to a discrete input at a first voltage, sinking a first current, wherein the input corresponds to a digital input high value and in response to the discrete input at a second voltage, sinking a second current, wherein the input corresponds to a digital high value. The first voltage is less than the second voltage and the first current is greater than the second current.

In an embodiment, a digital input module for use in a process automation controller is disclosed. The digital input module comprises a plurality of digital input channels, each channel to sink a first current when a digital high value is received from a contactor input device and to sink a second current when the digital high value is received from a digital logic device. The first current is greater than the second current.

These and other features will be more clearly understood from the following detailed description taken in conjunction with the accompanying drawings and claims.

### BRIEF DESCRIPTION OF THE DRAWINGS

For a more complete understanding of the present disclosure, reference is now made to the following brief description, taken in connection with the accompanying drawings and detailed description, wherein like reference numerals represent like parts.

FIG. 1 is a block diagram of a process automation controller according to an embodiment of the disclosure.

FIG. 2 is a block diagram of a digital input module according to an embodiment of the disclosure.

FIG. 3A is a schematic diagram of a first portion of a digital input channel according to an embodiment of the disclosure.

FIG. 3B is a schematic diagram of a second portion of a digital input channel according to an embodiment of the disclosure.

FIG. 3C is a schematic diagram of a third portion of a digital input channel according to an embodiment of the disclosure.

FIG. 4 is a flow chart of a method according to an embodiment of the disclosure.

FIG. 5 illustrates an exemplary computer system suitable for implementing the several embodiments of the disclosure.

### DETAILED DESCRIPTION

It should be understood at the outset that although illustrative implementations of one or more embodiments are illustrated below, the disclosed systems and methods may be implemented using any number of techniques, whether currently known or in existence. The disclosure should in no way be limited to the illustrative implementations, drawings, and techniques illustrated below, but may be modified within the scope of the appended claims along with their full scope of equivalents. Additionally, the disclosure should not be limited to only the voltage, current, and circuit values described below.

In an embodiment, a process automation controller having a digital input module supporting universal digital inputs is disclosed. In a preferred embodiment, the digital input module provides a plurality of digital input channels in a high density package without internal fan cooling or other active cooling and is designed for use in an ambient temperature environment of about 130 degrees Fahrenheit (55 degrees Celsius) with no more than a 54 degree Fahrenheit temperature rise (30 degree Celsius) inside the package and/or housing containing the digital input module. Each digital input channel is able to receive either of a logic input or a contactor input, hence the term universal digital input.

The digital input module supports connecting either a logic input to an external connector of the digital input module associated with a first digital input channel or connecting a contactor input to the external connector of the digital input module, and the first digital input channel will receive either contactor input or logic input. In process automation control, it is understood that a contactor input may present a voltage of about positive 12 volts as an input to a controller when the subject contactor is closed and may present a voltage of about negative 3 volts to about positive 5 volts when the subject contactor is open. It is likewise understood that a logic input may present a voltage of from about positive 22 volts to about positive 30 volts as an input to the controller when the subject logic input is high and a voltage of from about negative 3 volts to about positive 5 volts when the logic input is low. To achieve power dissipation goals in the context of the severe design constraints identified above, each digital input channel incorporates a circuit that allows a first level of current to flow into the digital input when a voltage associated with a closed contactor is input to the subject digital input channel and a second level of current to flow into the digital input when a voltage associated with a logic input high is input to the subject digital input channel. By reducing the current that flows when the higher voltage is present—for example when the logic input high is present—the power dissipation is reduced with reference to the power dissipation that would occur at this higher voltage if the current were not reduced.

In an embodiment, the majority of the input current to the digital input channel may flow through a first resistor and a second resistor in series when a voltage associated with a logic input high is input, while the majority of the input current to the digital input channel is flowed around the first resistor and through the second resistor when a voltage associated with a closed contactor is input. It will be appreciated by those skilled in the art that some stray input current may be sunk in transistor bias circuitry in the digital input channel. Because the resistance of resistors in series adds, the input resistance presented to a logic input high is greater and reduces the input current relative to what the input current would have been if the input resistance was provided only by the second resistor. Because the power dissipation is related to the product of voltage times current, to control power dissipation when a logic input high is present, the input resistance is increased to reduce the input current. Using exemplary numbers, in an embodiment, the digital input channel may sink about 2 mA when a logic input high presents a voltage of about 30 volts at the input (about 60 mW power dissipation) and may sink about 4 mA when a closed contactor presents a voltage of about 18 volts at the input (about 72 mW power dissipation). If the input resistance did not change and the input current from the logic input was equal to or greater than the 4 mA associated with the contactor input, the power dissipated by the digital input channel would be about 120 mW, which may be excessive power dissipation in the context of the aggressive design criteria identified above.

In an embodiment, the changed input resistance presented to the digital inputs is implemented by a transistor that saturates and provides substantially a short circuit from its emitter to collector around the first resistance at a first voltage level associated with a closed contactor and that is reverse biased and provides substantially an open circuit from its emitter to collector in the bypass loop around the first resistor (hence, the first resistance contributes additively to the input resistance of the digital input channel). In other embodiments, however, other circuitry may be employed to increase the input resistance presented by the digital input channel and/or to reduce the current at a higher voltage. For example, some other circuitry may be employed to switch the bypass loop around the first resistor open and closed. For example, some other circuitry may be employed to change the input resistance presented by the digital input channel.

The challenge of providing a universal digital input module providing many digital inputs in a small package volume for operation in a high temperature environment is significant. By selectively altering the current sunk by the universal digital input module in response to the voltage level, the universal digital input module can sink the substantial current desired to promote proper operation of contactors and can sink less current when receiving an input from a logical device at a higher voltage, thereby avoiding dissipating excessive heat. This innovative approach promotes greater flexibility of use of the universal digital input module.

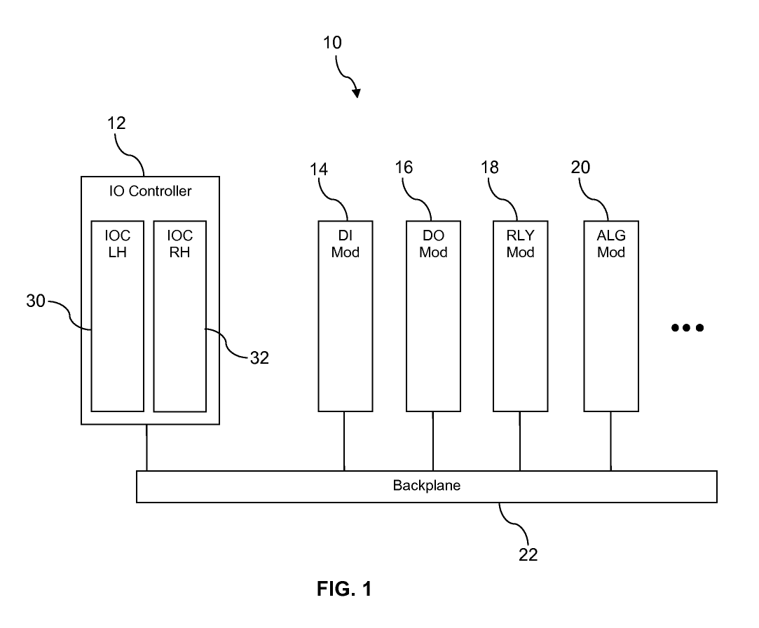

Turning now to FIG. 1, a process automation controller 10 is described. The process automation controller 10 may comprise an input output (IO) controller 12, one or more digital input (DI) module 14, one or more digital output (DO) module 16, one or more relay module 18, and one or more analog module 20. In some contexts, the DI module 14, the DO module 16, the relay module 18, and the analog module 20 may be collectively referred to as input output (IO) modules. In some embodiments, the process automation controller 10 may omit one or more of the different types of IO modules, as for example in different process environments and/or when a plurality of process automation controllers 10 may be used to control the subject process. The IO controller 12 communicates with the 10 modules via a backplane 22.

In an embodiment, the IO controller 12 may communicate with the IO modules using a serial peripheral interface (SPI) communication protocol. According to the SPI communication protocol, the IO controller 12 commands a specific IO module to transmit input to the IO controller 12 over the backplane 22 and commands a specific IO module to receive commands from the IO controller 12 over the backplane 22. In an alternative embodiment, the IO controller 12 may communicate with the IO modules according to a different communication protocol or a different communication design. The IO controller 12 may comprise one or more interfaces (not shown) to provide access to the IO controller 12, for example a network interface, an interface for connecting a user interface device such as a laptop computer, an interface to connect diagnostic and/or test equipment, and the like. In an embodiment, the IO controller 12 may comprise a power supply (not shown) to source power to the IO modules. It is understood that the process automation controller 10 may comprise other components that are not depicted in FIG. 1.

In an embodiment, the process automation controller IO is suitable for use in environments where temperatures may range from about 32 degrees Fahrenheit (about 0 degrees Celsius) to about 130 degrees Fahrenheit (about 55 degrees Celsius). The IO modules are designed for convective cooling without employing active cooling, for example fans. It is understood by those skilled in the art that semiconductor devices become increasingly subject to failure as their operating temperature increases above their specified operating temperature range. The design and operating principles of the disclosed process automation controller IO may be applied to electronics specified at different operating temperature ranges.

It is desirable to provide a DI module 14 and a DO module 16 that have increased IO density (a greater number of digital input channels per DI module 14 and/or a greater number of digital output channels per DO module 16). In an embodiment, the DI module 14 provides at least 16 digital input channels within about 1 linear inch of DIN rail. As is known to those of skill in the art, DIN rail is a standardized metal rail used for mounting control equipment into equipment racks. A linear inch of DIN rail refers to the width of modules that are mounted to the DIN rail. In an embodiment, the DI module 14 is less than about 90 mm in height and less than about 82 mm in depth. In an embodiment, the DI module 14 comprises the 16 digital input channel circuitry, a micro controller, a module power supply, an isolated contactor power supply, and a terminal unit comprising two field wiring blocks each comprising a 2.5 mm² screw terminal. In an embodiment, the process automation controller 10, including the DI module 14, may be mounted in an equipment rack using some other mechanism than DIN rail, for example gear plate mounting.

In some applications, for example controlling a glass manufacturing plant, the process automation controller 10 may be expected to be in continuous operation controlling equipment for fourteen or more years without powering down and/or without failing. Failure of IO modules or the IO controller 12 may cause substantial financial loses, for example materials that need to be scraped or otherwise destroyed. Additionally, failure of IO modules or the IO controller 12 may create unsafe working conditions. Hence, the process automation controller 10 may be designed to be failsafe and to have redundant processing capabilities. Those skilled in the art of electronics engineering, and more specifically the art of designing electronic controls, will appreciate the severity of these design constraints.

In an embodiment, the IO controller 12 may comprise a left hand input output controller (LH IOC) 30 and a right hand input output controller (RH IOC) 32. In normal operation, one of the IOC 30, 32 operates in active mode and the other IOC 30, 32 operates in standby mode. The active IOC 30, 32 communicates with the IO modules, receiving inputs, processing the inputs according to control strategies stored in the active IOC 30, 32, and outputting commands. In an embodiment, the standby IOC 30, 32 may communicate occasionally with the IO modules to monitor its own health.

The DO module 16 provides digital outputs to devices coupled to the process being controlled, for example, thyristors, solenoids, and relays which may in turn be coupled to electric ovens, pressure valves, flow control valves. In an embodiment, the DO module 16 may comprise 16 digital output channels, each operable to output a digital signal to a process device, but in another embodiment, the DO module 16 may comprise some other number of digital output channels.

The relay module 18 drives relays and solenoids in the process being controlled. For example, the relay module 18 may source power to cause a relay to change state to provide electrical power to a motor, thereby turning the motor on. The relay module 18 may source power to cause a relay to change state to provide electric power to an electric furnace. For example, a relay when closed may supply 0.5 amps at 230 VAC or may supply 2 amps at 50 VDC. The relay module 18 may source power to activate a solenoid opening a door to dispense material into a vat or hopper. In an embodiment, the relay module 18 may comprise 8 relay channels each operable to control one relay, but in other embodiments the relay module 18 may comprise a different number of relay channels. The relay module 18 may source power to activate a solenoid engaging a clutch to couple power from a prime mover to a mechanical assembly like a conveyor belt or an auger.

While one analog module 20 is depicted in FIG. 1, in an embodiment a variety of different analog modules 20 may be part of the process automation controller 10. For example, the process automation controller 10 may comprise one or more first analog input module for receiving analog voltage inputs from thermocouples, converting these analog voltage inputs to digital values, and conveying the digital values to the IOC 30, 32; one or more second analog input module for receiving analog voltage inputs from conditioned thermocouples, converting these analog voltage inputs to digital values, and conveying the digital values to the IOC 30, 32; and one or more third analog input module for receiving analog voltage inputs from other process devices and/or sensors, converting these analog voltage inputs to digital values, and conveying the digital values to the IOC 30, 32. The process automation controller 10 may comprise one or more frequency input modules for receiving analog voltage inputs at a higher frequency than can be accommodated by a digital input module 14. Additionally, the process automation controller 10 may comprise one or more analog output module that receives commands as digital values from the IOC 30, 32, converts the digital values to analog voltages, and transmits the analog voltages to control devices in the process environment, such as to modulate valves and other substantially continuously varying devices. The valves may control the flow of liquids or gases, for example chemicals, crude oil, nitrogen gas, natural gas, and other.

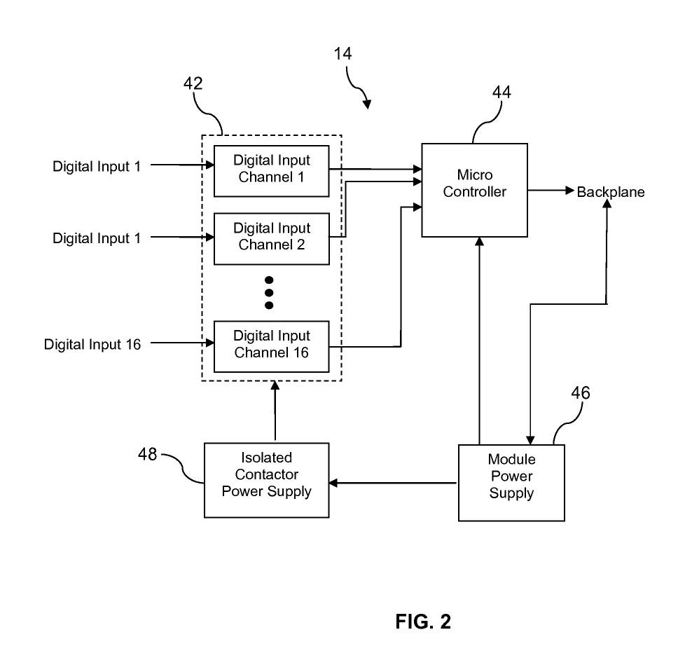

Turning now to FIG. 2, the DI module 14 is described. In an embodiment, the DI module 14 comprises a plurality of digital input channels 42, a microcontroller 44, and a module power supply 46. In an embodiment, the DI module 14 may comprise an optional isolated contactor power supply 48. Alternatively, a power supply external to the DI module 14 may supply power to contactors. The DI module 14 may further comprise other components that are not shown in FIG. 2. The DI module 14 receives digital inputs from either contactors or logic inputs, for example a first digital input channel receives a first digital input from either a contactor or a logic input, a second digital input channel receives a second digital input from either a contactor or a logic input, and a sixteenth digital input channel receives a sixteenth digital input from either a contactor or a logic input. In an embodiment, the DI module 14 comprises 16 digital input channels, but in another embodiment the DI module 14 may comprise a different number of digital input channels.

The module power supply 46 or the isolated contactor power supply 48 provides source voltage to one or more power terminal of a terminal block for sourcing about 18 volts to contactors. For example, a first wire may be coupled to the power terminal at one end of the wire and a first side of a contactor at the other end of the wire. A second wire may be coupled to a second side of the contactor at one end of the wire and to a digital input terminal on the terminal block at the other end of the wire. When the contactor closes, a circuit is formed from the power terminal over the first wire, through the contactor, over the second wire, and to one of the digital input channels 42. In an embodiment, the capacitor of a low pass RC filter in the input circuitry of the digital input module 14 may sink a 60 milliamp to 70 milliamp current for about 200 nanoseconds. This transient current spike through the contacts helps to clear off the oxidation layer on the contacts. In other embodiments, however, different currents may flow for different time durations after the contactor closes. Because of voltage drop across resistors and electronic components in the digital input module 14, the voltage across an open contactor may be less than 18 volts, for example about 12 volts to 14 volts.

The microcontroller 44 receives commands from the IOC 30, 32 via the backplane 22 to transmit digital inputs to the IOC 30, 32. When the microcontroller 44 receives the transmit command, the microcontroller 44 reads the inputs received by the digital input channels 42 and transmits these digital input values to the IOC 30, 32 over the backplane 22. As discussed in further detail below, the digital input channels 42 employ opto-isolators to electrically isolate their inputs from the signal that they propagate to the microcontroller 44. Thus, the microcontroller 44 may be said to read the opto outputs of the digital input channels 42.

The digital input channels 42 receive digital inputs from either contactors or logic input devices. In an embodiment, any digital input channel, for example a first digital input channel, may receive and process a contactor input or a logical input without physically altering the digital input channel. For example, if a first terminal is associated with the input to the first digital input channel, the first terminal may be coupled to a contactor device, and the first digital input channel processes the digital inputs from the contactor device. If the contactor device is decoupled from the first terminal and a logic input device is coupled to the first terminal instead, the first digital input channel processes the digital inputs of the logic input device. There is no need to access the interior of a package of the DI module 14 to make it suitable for processing a contactor input versus a logic input, simply connect different devices to the external terminal block, and the subject digital input channels 42 process the inputs appropriately.

The digital input channels 42 associate a low digital value with an input voltage less than 5 volts and a high digital value with an input voltage equal to or greater than 11 volts. The opto outputs of the digital input channels 42 are inverted with respect to the inputs. For example, when a high digital value is presented at the input of the digital input channel, the opto output is a digital low value; when a low digital value is presented at the input of the digital input channel, the opto output is a digital high value. To support industry standards, the digital input channels 42 sink a small amount of current when a digital low value is input. According to one industry standard that may be used in process automation control, the BS EN61131:2 standard, a logic low is defined to be any voltage in the range negative 3 volts to positive 5 volts with a maximum current of 15 mA and a logic high is defined to be any voltage in the range positive 11 volts to positive 30 volts with a current in the range from a minimum of 2 mA to a maximum of 15 mA. The transition logic zone is defined from positive 5 volts to positive 11 volts with a current in the range from a minimum of 1.5 mA to a maximum of 15 mA. The digital value of a voltage in the transition logic zone may be either high or low.

A contactor input may present a digital high value of about positive 11 volts to positive 18 volts to the input of the digital input channels 42, and a logic input may present a digital high value of about positive 24 volts to positive 30 volts. The digital input channels 42 present a first input resistance when the input voltage is less than a threshold and present a second input resistance when the input voltage is greater than the threshold. In an embodiment, the threshold is in the range from about positive 18 volts to about positive 22 volts, but in another embodiment the threshold may have a different value. The different input resistances promote reducing the current when a logic input digital high value is presented at the input of the digital input channel and hence helps to manage power dissipation and heat generation by the DI module 14.

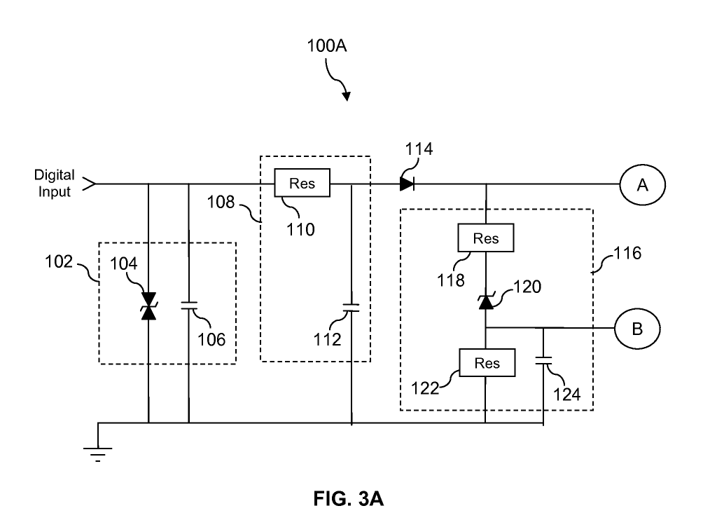

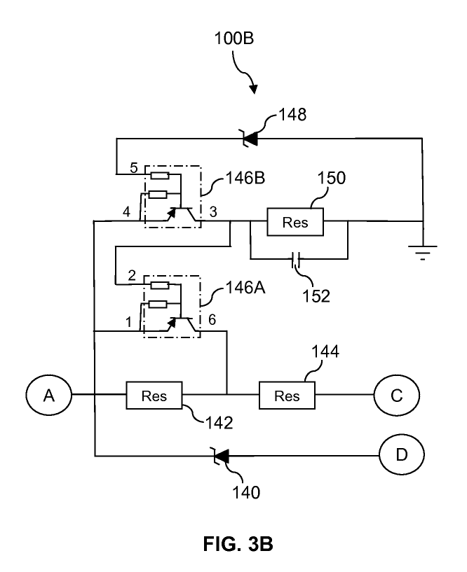

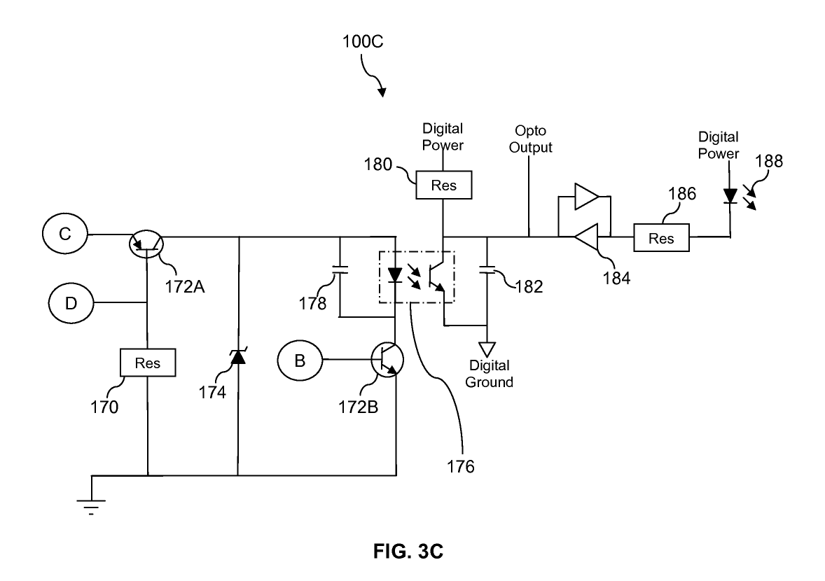

Turning now to FIG. 3A, FIG. 3B, and FIG. 3C, a digital input channel 100 is described. With reference to FIG. 3A, an input voltage clamp 102 is shown comprising a transient voltage suppression (TVS) diode 104 (also referred to in some contexts as a transorb) and a capacitor 106 in parallel. In another embodiment, the input voltage clamp 102 may be implemented with different components or may be omitted from the digital input channel 100. The input voltage clamp 102 attenuates transient voltage spikes, for example voltage spikes associated with motors turning on or off, and reduces the propagation of these transients from the digital input into the remainder of the digital input channel 100. An input filter 108 is shown comprising a resistor 110 and a capacitor 112. The input filter 108 implements a low pass filter. The input filter 108 shown is an RC-type filter, but it is understood that other types of filters may be employed in other embodiments. The resistor of the RC-type filter embodiment may help with hysteresis when going from about 30 volts to about 0 volts to dampen and/or to avoid oscillation. In some contexts this may also be referred to as debouncing the transition from a first current level to a second current level and from the second current level to the first current level as a voltage input to the digital input channel 100 changes. As mentioned above, the capacitor of the RC-type filter embodiment may provide a transient spark when contactors close to help clean off an oxidation layer on the contacts of the contactor. Additionally, the input filter 108 may be implemented as an RC-type filter having additional branches of resistors and capacitors. The diode 114 protects against reverse polarization. In an embodiment, the input filter 108 and/or the diode 114 may be omitted from the digital input channel 100.

A bias circuit 116 provides base to emitter bias for an NPN transistor 172B that is discussed later. The bias circuit 116 comprises a resistor 118, a zener diode 120, a resistor 122, and a capacitor 124. The capacitor 124 shunts any AC current to ground. In combination with the rest of the digital input channel circuitry, the bias circuit 116 keeps the NPN transistor 172B biased off until a voltage of about 8 volts is input at the digital input. In an embodiment, the zener diode 120 has a breakdown voltage of about 6 volts. In another embodiment, however, the zener diode 120 may have a different breakdown voltage. The resistance of the resistors 118, 122 may be relatively high, in consideration of the temperature environment in which the digital input channel 100 is designed to operate. For example, in an embodiment the resistance of each of the resistors 118, 122 may be about 100 kΩ. In another embodiment, however, a different resistance value may be employed for the resistors 118, 122. When the voltage across the zener diode 120 is less than the breakdown voltage of the zener diode 120, little current flows in the bias circuit 116 and the voltage at point B is substantially at ground. When the voltage across the zener diode 120 is at or above the breakdown voltage of the zener diode 120, current flows in the bias circuit 116 (relatively little current shunts to the base of the NPN transistor 172B), through the resistor 122, thereby raising the voltage at point B and forward biasing the base to emitter junction of the NPN transistor 172B.

With reference now to FIG. 3B, a first resistor 142 is shown in series with a second resistor 144. A first PNP transistor 146A and a second PNP transistor 146B are shown. In an embodiment, the PNP transistors 146 may be part of a single chip package and fabricated on a single semiconductor substrate, but in another embodiment they may be separate chip packages. A zener diode 148, a resistor 150, and a capacitor 152 comprise the biasing circuitry for the two PNP transistors 146. In an embodiment, the zener diode 148 has a reverse breakdown voltage of about 18 volts, but in another embodiment the zener diode 148 may have another reverse breakdown voltage.

When the zener diode 148 is operated below its breakdown voltage, substantially no current passes from the base of the second PNP transistor 146B through the zener diode 148 to ground, the second PNP transistor 146B is turned off, and substantially no current passes from the emitter to the collector of the second PNP transistor 146B. When a digital logic high is input having a voltage below the breakdown voltage of the zener diode 148, for example a voltage in the range of about positive 11 volts to about positive 18 volts, the zener diode 148 is below its breakdown voltage and the second PNP transistor 146B is turned off. Under this circumstance, the first PNP transistor 146A is forward biased and saturates. In the saturated condition, the emitter to collector path of the first PNP transistor 146A effectively provides a short around the first resistor 142, and the current flowing from point A to point C is effectively limited by the second resistor 144.

When a digital logic high is input having a voltage in the range of about positive 18 volts to about positive 30 volts and the voltage across the zener diode 148 is at or above the breakdown voltage of the zener diode 148, the zener diode 148 conducts current, the second PNP transistor 146B is forward biased, current flows from the emitter to the collector of the second PNP transistor 146B, through the resistor 150, and thence to ground. In this condition, the first PNP transistor 146A is biased off, substantially no current passes from the emitter to the collector of the first PNP transistor 146A, and the current flowing from point A to point C is effectively limited by the series combination of the first resistor 142 and the second resistor 144. In some contexts, when the zener diode 148 has the threshold voltage applied in the reverse bias sense (in a forward biased condition a zener diode is known to conduct current much as a normal diode conducts current when forward biased) and the zener diode 148 conducts current in the reverse direction, the zener diode 148 may be said to operate in an avalanche mode. When the zener diode 148 has less than the threshold voltage applied in the reverse bias sense, the zener diode 148 may be said to operate in a non-avalanche mode.

In an embodiment, a zener diode 140 has a breakdown voltage of about 4.3 volts, but in another embodiment the zener diode 140 may have a different breakdown voltage. The zener diode 140 limits the voltage between point A and point D and hence effectively limits the current from point A to point C (the emitter to base junction voltage of the PNP transistor 172A to be discussed later may be assumed to be a constant voltage, for example about 0.7 volts or some other constant voltage, when the PNP transistor 172A is saturated, as it is when a digital input high value is received). In an embodiment, the resistance of the first resistor 142 and the second resistor 144 may be substantially equal. Hence, in an embodiment, with a digital input in the range of about positive 11 volts to about positive 18 volts, the first resistor 142 is bypassed, about 3 volts is applied across the second resistor 144, and a current of about 4 mA may flow through the second resistor 144. In an embodiment, with a digital input in the range of about positive 18 volts to positive 30 volts, the first resistor 142 is not bypassed, about 3 volts is applied across the series combination of the first resistor 142 and the second resistor 144, and a current of about 2 mA may flow through the resistors 142, 144. In another embodiment, these currents may be different.

The circuitry illustrated in FIG. 3B may be referred to in some contexts as a voltage sensing current limiter. It is understood that the function of the voltage sensing current limiter may be provided in some embodiments with different components. For example, in an embodiment, one or more of the two PNP transistors 146 may replaced by a relay. In an embodiment, the circuitry illustrated in FIG. 3B may be designed to include a plurality of stages of voltage sensing current limiter. For example, in an embodiment, an additional resistor may be connected in series with the first resistor 142 between the diode 114 and the first resistor 142 and in parallel with a voltage sensing bypass circuit similar to that provided by PNP transistors 146, zener 148, resistor 150, and capacitor 152. The reverse breakdown voltages of the zener 148 and the zener in the additional voltage sensing current limiter may be adjusted to breakdown at appropriate voltages to maintain current through the series resistors 142, 144 within a desired range based on the input voltage. By using two or more stages of voltage sensing current limiting, the maximum current through the series resistors 142, 144 may be reduced and hence the power dissipation of the digital input channel 100 reduced. In combination with the present disclosure, one skilled in the art will readily be able to choose how many stages of voltage sensing current limiting to employ to achieve a desirable tradeoff between circuit complexity, component cost, and component foot print versus power dissipation.

With reference now to FIG. 3C, when a voltage in excess of about positive 11 volts is present to the digital input, an NPN transistor 172B is biased in saturation via point B, a PNP transistor 172A is biased in saturation and drives current through the light emitting diode (LED) portion of an opto-isolator 176, the transistor of the opto-isolator 176 is turned on, dropping the voltage of the opto output to substantially digital ground—a logic low value. When a voltage of less than about positive 5 volts is present to the digital input, the NPN transistor 172B is biased off via point B, substantially no current flows through the LED of the opto-isolator 176, the transistor of the opto-isolator 176 is turned off, and the opto output is raised substantially to the value of the digital power input—a logic high value. In an embodiment, a light emitting diode (LED) 188, coupled to the opto output by a bi-directional buffer 184 and a resistor 186, may provide visual indications of the opto output logic states on a front panel of the DI module 14. The circuitry of FIG. 3C may further comprise resistor 170, capacitor 178, resistor 180, and capacitor 182.

In an embodiment, the PNP transistor 172A and the NPN transistor 172B may be part of a single chip package and may be fabricated on the same semiconductor substrate. In another embodiment, however, the PNP transistor 172A and the NPN transistor 172B may be separate chip packages. In an embodiment, the bi-directional buffer 184 may be replaced with a one-way buffer. In an embodiment, a zener diode 174 may be provided to promote sinking a small amount of input current when the input voltage is between positive 5 volts and positive 11 volts in order to comply with one or more commercial standard. In an embodiment, the zener diode 174 may have a breakdown voltage of about 3 volts, but in another embodiment, the zener diode 174 may have a different breakdown voltage.

While a specific implementation of a digital input channel 100 has been described above, it is understood that the present disclosure contemplates other circuits for changing the input current of a digital input channel based on the voltage level of the digital input. For example, in an embodiment, the digital input channel 100 may omit the opto-isolation functionality and still provide two different current levels based on voltage level of the digital input. As is understood by those skilled in the art, the sense of voltage polarity of the output of the opto-isolator 176 could be reversed by placing another transistor in the circuit of FIG. 3C. In an embodiment, for example incorporating the extra transistor, a digital high input may be transmitted onto the backplane 22 by the digital input module 14 as a digital high and a digital low input may be transmitted onto the backplane 22 by the digital input module 14 as a digital low (that is, the digital input module 14 need not invert the inputs). In an embodiment, a different circuit configuration may be employed to effectively short the first resistor 142. In an embodiment, another circuit configuration may be employed to change the input resistance presented at the digital input. In an embodiment, portions of the digital input channel 100 may be integrated on a semiconductor chip.

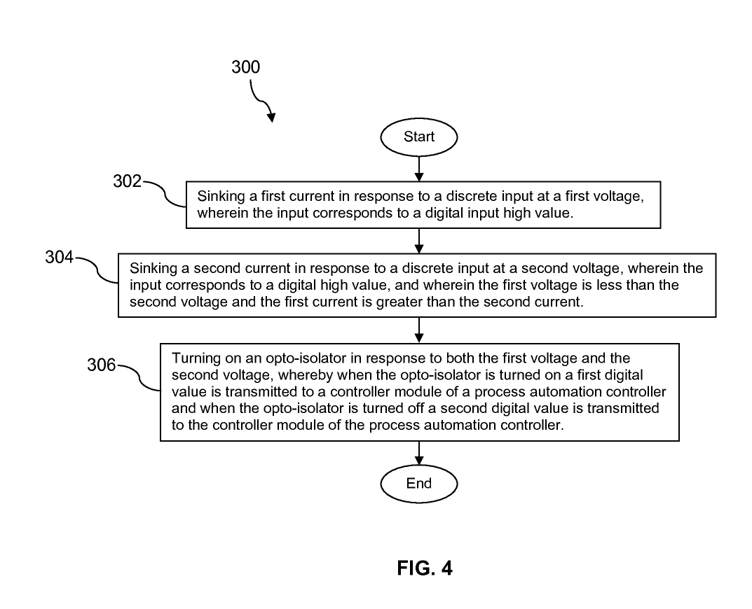

Turning now to FIG. 4, a method 300 is described. At block 302, a first current is sunk by a digital input channel in response to a discrete input at a first voltage, wherein the input corresponds to a digital high input value. At block 304, a second current is sunk by the digital input channel in response to a discrete input at a second voltage, wherein the input corresponds to a digital high value, and wherein the first voltage is less than the second voltage, and the first current is greater than the second current. At block 306, an opto-isolator is turned on in response to both the first voltage and the second voltage, whereby when the opto-isolator is turned on a first digital value is transmitted to a controller module of a process automation controller and when the opto-isolator is turned off a second digital value is transmitted to the controller module of the process automation controller. In an embodiment, the first current is greater than 3.5 mA, and the second current is less than 2.75 mA. In an embodiment, the first voltage is less than positive 18.5 V, and the second voltage is more than positive 22 V. As is understood by those skilled in the art, the sense of voltage polarity of the output of the opto-isolator could be reversed by placing another transistor in the circuit of FIG. 3C. In another embodiment, for example incorporating the extra transistor, a digital high input may be transmitted onto the backplane 22 by the digital input module 14 as a digital high and a digital low input may be transmitted onto the backplane 22 by the digital input module 14 as a digital low (that is, the digital input module 14 need not invert the inputs).

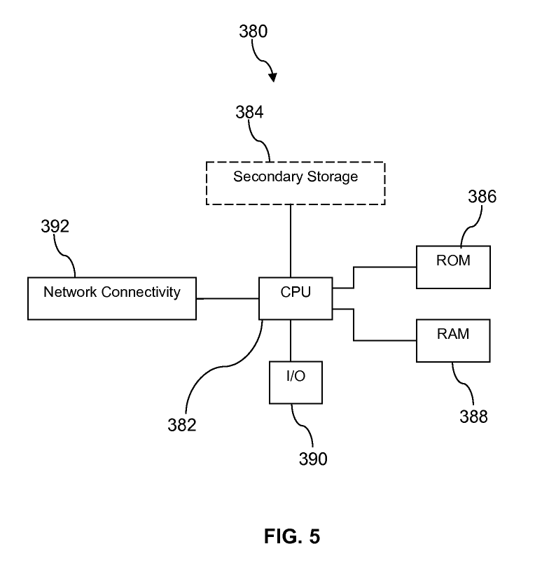

FIG. 5 illustrates a computer system 380 suitable for implementing one or more embodiments disclosed herein. For example, the left hand IO controller 30 and the right hand IO controller 32 each may be implemented as a computer system having an architecture consistent with that of the computer system 380. The computer system 380 includes a processor 382 (which may be referred to as a central processor unit or CPU) that is in communication with memory devices including optional secondary storage 384, read only memory (ROM) 386, random access memory (RAM) 388, input/output (I/O) devices 390, and network connectivity devices 392. The processor 382 may be implemented as one or more CPU chips.

It is understood that by programming and/or loading executable instructions (e.g., control strategies and/or control programs) onto the computer system 380, at least one of the CPU 382, the RAM 388, and the ROM 386 are changed, transforming the computer system 380 in part into a particular machine or apparatus having the novel functionality taught by the present disclosure. It is fundamental to the electrical engineering and software engineering arts that functionality that can be implemented by loading executable software into a computer can be converted to a hardware implementation by well known design rules. Decisions between implementing a concept in software versus hardware typically hinge on considerations of stability of the design and numbers of units to be produced rather than any issues involved in translating from the software domain to the hardware domain. Generally, a design that is still subject to frequent change may be preferred to be implemented in software, because re-spinning a hardware implementation is more expensive than re-spinning a software design. Generally, a design that is stable that will be produced in large volume may be preferred to be implemented in hardware, for example in an application specific integrated circuit (ASIC), because for large production runs the hardware implementation may be less expensive than the software implementation. Often a design may be developed and tested in a software form and later transformed, by well known design rules, to an equivalent hardware implementation in an application specific integrated circuit that hardwires the instructions of the software. In the same manner as a machine controlled by a new ASIC is a particular machine or apparatus, likewise a computer that has been programmed and/or loaded with executable instructions may be viewed as a particular machine or apparatus.

The secondary storage 384 is typically comprised of one or more disk drives or tape drives and is used for non-volatile storage of data and as an over-flow data storage device if RAM 388 is not large enough to hold all working data. Secondary storage 384 may also comprise flash memory, static RAM (SRAM), and network storage. Secondary storage 384 may be used to store programs which are loaded into RAM 388 when such programs are selected for execution. Due to the harsh temperature environment and the long continuous operation design of the process automation controller 10, however, the secondary storage 384 may be omitted from the IO controller 12. The ROM 386 is used to store instructions and perhaps data which are read during program execution. ROM 386 is a non-volatile memory device which typically has a small memory capacity relative to the larger memory capacity of secondary storage 384. The RAM 388 is used to store volatile data and perhaps to store instructions. Access to both ROM 386 and RAM 388 is typically faster than to secondary storage 384. The secondary storage 384, the RAM 388, and/or the ROM 386 may be referred to in some contexts as non-transitory storage and/or non-transitory computer readable media.

I/O devices 390 may include printers, video monitors, liquid crystal displays (LCDs), touch screen displays, keyboards, keypads, bar code readers, switches, dials, mice, track balls, voice recognizers, card readers, paper tape readers, or other well-known input devices.

The network connectivity devices 392 may take the form of modems, modem banks, Ethernet cards, universal serial bus (USB) interface cards, serial interfaces, token ring cards, fiber distributed data interface (FDDI) cards, wireless local area network (WLAN) cards, radio transceiver cards such as code division multiple access (CDMA), global system for mobile communications (GSM), long-term evolution (LTE), worldwide interoperability for microwave access (WiMAX), and/or other air interface protocol radio transceiver cards, and other well-known network devices. These network connectivity devices 392 may enable the processor 382 to communicate with an Internet or one or more intranets. With such a network connection, it is contemplated that the processor 382 might receive information from the network, or might output information to the network in the course of performing the above-described method steps. Such information, which is often represented as a sequence of instructions to be executed using processor 382, may be received from and outputted to the network, for example, in the form of a computer data signal embodied in a carrier wave.

Such information, which may include data or instructions to be executed using processor 382 for example, may be received from and outputted to the network, for example, in the form of a computer data baseband signal or signal embodied in a carrier wave. The baseband signal or signal embodied in the carrier wave generated by the network connectivity devices 392 may propagate in or on the surface of electrical conductors, in coaxial cables, in waveguides, in an optical conduit, for example an optical fiber, or in the air or free space. The information contained in the baseband signal or signal embedded in the carrier wave may be ordered according to different sequences, as may be desirable for either processing or generating the information or transmitting or receiving the information. The baseband signal or signal embedded in the carrier wave, or other types of signals currently used or hereafter developed, may be generated according to several methods well known to one skilled in the art. The baseband signal and/or signal embedded in the carrier wave may be referred to in some contexts as a transitory signal.

The processor 382 executes instructions, codes, computer programs, scripts which it accesses from hard disk, floppy disk, optical disk (these various disk based systems may all be considered secondary storage 384), ROM 386, RAM 388, or the network connectivity devices 392. While only one processor 382 is shown, multiple processors may be present. Thus, while instructions may be discussed as executed by a processor, the instructions may be executed simultaneously, serially, or otherwise executed by one or multiple processors. Instructions, codes, computer programs, scripts, and/or data that may be accessed from the secondary storage 384, for example, hard drives, floppy disks, optical disks, and/or other device, the ROM 386, and/or the RAM 388 may be referred to in some contexts as non-transitory instructions and/or non-transitory information.

In an embodiment, the computer system 380 may comprise two or more computers in communication with each other that collaborate to perform a task. For example, but not by way of limitation, an application may be partitioned in such a way as to permit concurrent and/or parallel processing of the instructions of the application. Alternatively, the data processed by the application may be partitioned in such a way as to permit concurrent and/or parallel processing of different portions of a data set by the two or more computers. In an embodiment, virtualization software may be employed by the computer system 380 to provide the functionality of a number of servers that is not directly bound to the number of computers in the computer system 380. For example, virtualization software may provide twenty virtual servers on four physical computers. In an embodiment, the functionality disclosed above may be provided by executing the application and/or applications in a cloud computing environment. Cloud computing may comprise providing computing services via a network connection using dynamically scalable computing resources. Cloud computing may be supported, at least in part, by virtualization software. A cloud computing environment may be established by an enterprise and/or may be hired on an as-needed basis from a third party provider. Some cloud computing environments may comprise cloud computing resources owned and operated by the enterprise as well as cloud computing resources hired and/or leased from a third party provider.

In an embodiment, some of the functionality disclosed above may be provided as a computer program product, for example control strategies and/or control programs. The computer program product may comprise one or more computer readable storage medium having computer usable program code embodied therein implementing the functionality disclosed above. The computer program product may comprise data, data structures, files, executable instructions, and other information. The computer program product may be embodied in removable computer storage media and/or non-removable computer storage media. The removable computer readable storage medium may comprise, without limitation, a paper tape, a magnetic tape, magnetic disk, an optical disk, a solid state memory chip, for example analog magnetic tape, compact disk read only memory (CD-ROM) disks, floppy disks, jump drives, digital cards, multimedia cards, and others. The computer program product may be suitable for loading, by the computer system 380, at least portions of the contents of the computer program product to the secondary storage 384, to the ROM 386, to the RAM 388, and/or to other non-volatile memory and volatile memory of the computer system 380. The processor 382 may process the executable instructions and/or data in part by directly accessing the computer program product, for example by reading from a CD-ROM disk inserted into a disk drive peripheral of the computer system 380. The computer program product may comprise instructions that promote the loading and/or copying of data, data structures, files, and/or executable instructions to the secondary storage 384, to the ROM 386, to the RAM 388, and/or to other non-volatile memory and volatile memory of the computer system 380.

While several embodiments have been provided in the present disclosure, it should be understood that the disclosed systems and methods may be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted or not implemented.

Also, techniques, systems, subsystems, and methods described and illustrated in the various embodiments as discrete or separate may be combined or integrated with other systems, modules, techniques, or methods without departing from the scope of the present disclosure. Other items shown or discussed as directly coupled or communicating with each other may be indirectly coupled or communicating through some interface, device, or intermediate component, whether electrically, mechanically, or otherwise. Other examples of changes, substitutions, and alterations are ascertainable by one skilled in the art and could be made without departing from the spirit and scope disclosed herein.

What is claimed is:

1. In a process automation controller, a universal digital input module, comprising a plurality of digital input channels, each channel to sink a first current at a first voltage level associated with an input having a digital high value and to sink a second current at a second voltage level associated with the input having a digital high value, wherein the first current is greater than the second current and wherein the first voltage is less than the second voltage.

2. The module of claim 1, wherein the first current is more than about 3.25 milliamperes (mA) and the second current is less than about 2.75 milliamperes.

3. The module of claim 1, wherein the first voltage is less than about positive 18.5 volts and the second voltage is greater than about positive 20 volts.

4. The module of claim 1, wherein the universal digital input module is operable for steady-state operation in a 130 degree Fahrenheit (55 degree Celsius) ambient environment for a year, wherein the universal digital input module does not contain active cooling.

5. The module of claim 4, wherein 16 digital input channels consume about 1 linear inch of DIN rail.

6. The module of claim 1, wherein each channel automatically sinks the first current at the first voltage level when receiving a digital input from a contactor device external to the process automation controller and sinks the second current at the second voltage level when receiving a digital input from a digital logic device external to the process automation controller.

7. The module of claim 1, wherein each channel automatically bypasses a resistor when receiving the input at the first voltage level and couples the resistor to the input when receiving the input at the second voltage level.

8. The module of claim 1, wherein each digital input channel comprises a resistor-capacitor (RC) input filter, wherein the resistor of the RC input filter debounces a transition from the first current to the second current and from the second current to the first current as a voltage input to the digital input channel changes.

9. In a process automation controller, a method of receiving a discrete input, comprising:
in response to a discrete input at a first voltage, sinking a first current, wherein the input corresponds to a digital input high value; and
in response to the discrete input at a second voltage, sinking a second current, wherein the input corresponds to a digital high value,
wherein first voltage is less than the second voltage and the first current is greater than the second current.

10. The method of claim 9, wherein sinking the first current comprises bypassing a line coupled to the discrete input around a resistor to reduce a series resistance in the current sink circuit path and sinking the second current comprises not bypassing the line coupled to the discrete input around the resistor.

11. The method of claim 10, wherein bypassing the resistor is performed by a transistor that is biased to operate in saturated mode when the discrete input is at the first voltage and wherein not bypassing the resistor is performed by the transistor that is reverse biased when the discrete input is at the second voltage.

12. The method of claim 11, wherein a zener diode having a breakdown voltage equal to or greater than the first voltage couples into the biasing circuit of the transistor and wherein the zener diode transitioning into avalanche operation mode and out of avalanche mode controls the transitioning of the transistor from saturated mode to reverse bias.

13. The method of claim 9, further comprising turning on an opto-isolator in response to the discrete input at both the first voltage and the second voltage, whereby when the opto-isolator is turned on a first digital value is transmitted to a controller module of the process automation controller and when the opto-isolator is turned off a second digital value is transmitted to a controller module of the process automation controller, wherein the first and second digital values consist of a high digital value and a low digital value, wherein when the first digital value is a high digital value the second digital value is a low digital value, and wherein when the first digital value is a low digital value the second digital value is a high digital value.

14. In a process automation controller, a digital input module, comprising a plurality of digital input channels, each channel to sink a first current when a digital high value is received from a contactor input device and to sink a second current when the digital high value is received from a digital logic device, wherein the first current is greater than the second current.

15. The module of claim 14, wherein the voltage of the high digital input received from a contactor device is in the range of about positive 11 volts to about positive 18 volts and wherein the voltage of the high digital input received from a digital logic device is in the range of about positive 24 volts to about positive 30 volts.

16. The module of claim 14, wherein the digital input module comprises a power supply that supplies positive 18 volt power for use by one or more contactor input devices.

17. The module of claim 14, wherein the digital input module comprises 16 digital input channels.

18. The module of claim 14, wherein the input received by the digital input channel is electrically isolated from the digital signal that the digital input channel propagates on to a controller module of the process automation controller.

19. The module of claim 14, wherein the digital input module processes both contactor inputs and digital logic inputs on one of the digital input channels in accord with a BS EN61131:2 standard without reconfiguring the digital input channel.

20. The module of claim 19, wherein each digital input channel comprises:
a transistor that bypasses a resistor to reduce an input resistance of the digital input channel when the transistor is operated in saturated mode and does not bypass the resistor when the transistor is operated in reverse bias mode, and
a zener diode having a breakdown voltage equal to or greater than a first voltage associated with a digital high value input by a contactor input device, wherein the zener diode is coupled into the biasing circuit of the transistor, and wherein the zener diode transitioning into avalanche operation mode and out of avalance operation mode controls the transitioning of the transistor from saturated mode to reverse bias mode.
